(19) United States
(12) Patent Application Publication
(10) Pub. No.: US 2016/0315163 A1
(43) Pub. Date: Oct. 27, 2016

(54) PROCESS FOR FORMING GATE INSULATORS FOR TFT STRUCTURES

(71) Applicant: L'AIR LIQUIDE, SOCIETE ANONYME POUR L'ETUDE ET L'EXPLOITATION DES PROCEDES GEORGES CLAUDE, PARIS (FR)

(72) Inventors: CHRISTIAN DUSSARRAT, TOKYO (JP); CLÉMENT LANSALOT-MATRAS, PRINCETON, NJ (US); ANTOINE COLAS, OZOIR LA FERRIERE (FR)

(21) Appl. No.: 15/198,980

(22) Filed: Jun. 30, 2016

(51) Int. Cl. H01L 29/49; H01L 29/66; H01L 21/02; H01L 29/786

(52) U.S. Cl. CPC H01L 29/4908; H01L 29/7869; H01L 29/78681; H01L 29/66969; H01L 29/66522; H01L 29/66742; H01L 21/02205; H01L 21/02181; H01L 21/02189; H01L 21/02271; H01L 29/517

(57) ABSTRACT

Precursors suitable for vapor deposition of layers in thin film transistors and electronic devices comprising such thin film transistors are disclosed.

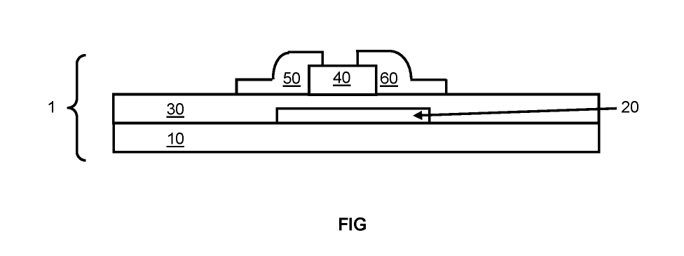

### FIELD OF THE INVENTION

Precursors suitable for vapor deposition of layers in thin film transistors and electronic devices comprising such thin film transistors are disclosed.

### BACKGROUND

Thin film transistors (TFTs) are incorporated in many devices, including integrated circuits and displays used in screens for electronic products, such as car instrument clusters, televisions, computer monitors, video games, mobile phones, notebook computers, digital cameras, and personal digital assistances. The TFTs serve as switching elements for each pixel unit in the display device. The TFT stack typically includes, at a minimum, a substrate, a gate electrode, a dielectric or insulating layer, source and drain electrodes, and a semiconductor channel layer.

Many TFT stacks now include Indium-Gallium-Zinc Oxide (IGZO) semiconductor channel layers. The IGZO semiconductor channel layer provides many advantages, such as room-temperature process availability, high optical transparency, high stability, high mobility and good-uniformity. In IGZO-TFTs, both the IGZO channel layer and insulating layer play a crucial role in the TFT performance.

ZrO₂ and HfO₂ have been proposed as suitable TFT dielectric insulating materials. [Lee et al., IEEE Electron Device Letters, VOL. 31, NO. 3, pp. 225-227 March 2010; Su et al., Journal of Display Technology, Vol. 8, No. 12, December 2012, pp. 695-698]. The ZrO₂ films are expected to be suitable due to its properties: a high dielectric constant (˜25), high breakdown field intensity (˜15 MV/cm), large band gap (˜5.6 eV), and relatively low leakage current [Id. Lee et al. at p. 225]. These ZrO₂ and HfO₂ materials may be deposited using argon sputtering, a technique that may induce stress in the film, inducing defaults and delamination in the TFT structures. In addition, there are still several drawbacks for high-k gate insulators produced by PVD based technologies such as large leakage current and surface roughness, which lead to reduction of the mobility, and instability. [Microelectronics Reliability 54 (2014) 2401-2405].

WO2015/071344 to Evonik Industries AG discloses low contact resistance TFTs having a gate insulator metal oxide layer formed of silicon oxide (SiOₓ), silicon nitride (SiN), aluminum oxide, hafnium oxide, titanium oxide, or a polymeric material. Evonik discloses that the metal oxide layer may be deposited using metal alkoxides, such as M(OR)ₓ or M(O—(CH₂)ₙ—OR), wherein M is a metal, preferably In; R is an alkyl group; and n is 2, or metal oxoalkoxides having the formula MₓO_{y}(OR)_{z}[O(R′O)_{c}H]ₐX_{b}[R″OH]_{d}, with M=Ga, Sn, Zn, AL Ti, Li, Na, K, Rb, Cs, Be, Mg, Ca, Sr, Ba, Hf, and/or Si, preferably M=In, Ga, Sn, and/or Zn; x=3-25; y=1-10; z=3-50; a=0-25; b=0-20; c=0-1; d=0-25; R, R′, and R′=organic residue, and X═F, Cl, Br, or I. Id. at pp. 32-33. Suitable deposition methods include printing, spraying, spin coating, dipping, vacuum deposition. chemical vapor deposition, evaporation, and sputtering.

Su et al. disclose the role of HfO₂/SiO₂ gate dielectrics on the reduction of low-frequent noise and the enhancement of a-IGZO TFT electrical performance using a 10 nm HfO₂ layer formed by ALD at 250° C. Id. Su et al. at p. 695, para II.

Consequently, a need remains for low temperature vapor deposition processes of the dielectric insulating layer of the TFT.

### SUMMARY

Thin film transistors (TFTs) are disclosed. The TFTs include a gate electrode formed on a substrate; a Group IV high k oxide gate insulating layer formed over the gate electrode and substrate; and a semiconductor channel layer formed over the Group IV high k oxide gate insulating layer. The semiconductor channel layer is selected from Indium Gallium Zinc Oxide (IGZO), amorphous IGZO, Indium Tin Zinc Oxide (ITZO), Aluminum Indium Oxide (AllnOx), Zinc Tin Oxide (ZTO), Zinc Oxynitride (ZnON), Magnesium Zinc Oxide, zinc oxide (ZnO), Rare Earth Indium Zinc Oxide ((RE)InZnO), InGaZnON, ZnON, ZnSnO, CdSnO, GaSnO, TiSnO, CuAlO, SrCuO, LaCuOS, GaN, InGaN, AlGaN, InGaAlN, or combinations thereof. The disclosed TFTs may include one or more of the following aspects:

The substrate being glass;

The substrate being flexible plastic;

The flexible plastic being a polyimide film;

The flexible plastic being a polyether ether ketone (PEEK) film; polyethylene naphthalate (PEN),

The flexible plastic being a polyethylene teraphalate film;

The flexible plastic substrate having a thickness ranging from approximately 5 microns to approximately 200 microns;

The flexible plastic substrate may be forced from a straight form into a curved form without damaging the substrate;

The gate electrode being Al;

The gate electrode being a CuAl alloy;

The gate electrode being Cu;

The gate electrode being a CuMg alloy;

The gate electrode being a CuP alloy;

the Group IV high k oxide gate insulating layer being ZrO₂;

the Group IV high k oxide gate insulating layer being HfO₂;

the semiconductor channel layer containing zinc and oxygen;

the semiconductor channel layer being indium gallium zinc oxide (IGZO);

the semiconductor channel layer being amorphous IGZO;

the semiconductor channel layer being indium tin zinc oxide;

the semiconductor channel layer being aluminum indium oxide;

the semiconductor channel layer being zinc tin oxide;

the semiconductor channel layer being zinc oxynitride;

the semiconductor channel layer being magnesium zinc oxide;

the semiconductor channel layer being zinc oxide;

the semiconductor channer layer being a Rare Earth Indium Zinc Oxide

the semiconductor channel layer being indium gallium zinc oxynitride;

the semiconductor channel layer being zinc oxynitride;

the semiconductor channel layer being zinc tin oxide;

the semiconductor channel layer being cadmium tin oxide;

the semiconductor channel layer being gallium tin oxide;

the semiconductor channel layer being titanium tin oxide;

the semiconductor channel layer being copper aluminum oxide;

the semiconductor channel layer being strontium copper oxide;

the semiconductor channel layer being lanthanum copper oxy sulfide;

the semiconductor channel layer being gallium nitride;

the semiconductor channel layer being indium gallium nitride;

the semiconductor channel layer being aluminum gallium nitride;

the semiconductor channel layer being indium gallium aluminum nitride;

the substrate being glass or plastic;

an etch stop layer formed on the semiconductor channel layer and the Group IV high k oxide gate insulating layer;

a source electrode and a drain electrode formed on the Group IV high k oxide gate insulating layer;

the source electrode and the drain electrode being spaced apart from each other on the Group IV high k oxide gate insulating layer;

a threshold voltage of the TFT being zero or <10V; and

the threshold voltage shift (ΔVₜₕ) being zero or <2V under negative bias stress.

Methods of synthesizing the above TFTs are also disclosed. The vapor of a Group IV-containing precursor and an oxygen source is introduced into a reaction chamber containing a substrate having a gate electrode thereon. A Group IV high k oxide gate insulating layer is deposited on the gate electrode and the substrate at a temperature of approximately 25° C. to approximately 350° C. using a vapor deposition process. The Group IV precursor being selected from the group consisting of:

a. Tetrakis(alkylamino) Zirconium (Zr(NR₂)₄) or Hafnium (Zr(NR₂)₄) wherein each R is independently selected from H; a C1-C5 hydrocarbyl group; or a C1-C5 fluoroalkyl group; and

b. Cyclopentadienyl-tris(alkylamino) Zirconium (Zr(R³R⁴R⁵R⁶R⁷Cp)(NR¹R²)₃) or Hafnium (Zr(R³R⁴R⁵R⁶R⁷Cp)(NR¹R²)₃) wherein each R¹, R², R³, R⁴, R⁵, R⁶, R⁷,

R⁸, R⁹ and R¹⁰ is independently selected from H; a C1-C5 hydrocarbyl group; or a C1-C5 fluoroalkyl group. The disclosed methods may include one or more of the following aspects:

the Group IV-containing precursor being tetrakis(dimethylamino) Zirconium;

the Group IV-containing precursor being tetrakis(ethylmethylamino) Zirconium;

the Group IV-containing precursor being tetrakis(diethylamino) Zirconium;

the Group IV-containing precursor being cyclopentadienyl tris(dimethylamino) Zirconium;

the Group IV-containing precursor being methylcyclopentadienyl tris(dimethylamino) Zirconium;

the Group IV-containing precursor being ethylcyclopentadienyl tris(dimethylamino) Zirconium;

the Group IV-containing precursor being t-butylcyclopentadienyl tris(dimethylamino) Zirconium;

the Group IV-containing precursor being di-isopropylcyclopentadienyl tris(dimethylamino) Zirconium;

the Group IV-containing precursor being trimethylgermylcyclopentadienyl tris(dimethylamino) Zirconium,

the Group IV-containing precursor being tetrakis(dimethylamino) Hafnium;

the Group IV-containing precursor being tetrakis(ethylmethylamino) Hafnium;

the Group IV-containing precursor being tetrakis(diethylamino) Hafnium;

the Group IV-containing precursor being cyclopentadienyl tris(dimethylamino) Hafnium;

the Group IV-containing precursor being methylcyclopentadienyl tris(dimethylamino) Hafnium;

the Group IV-containing precursor being ethylcyclopentadienyl tris(dimethylamino) Hafnium;

the Group IV-containing precursor being t-butylcyclopentadienyl tris(dimethylamino) Hafnium;

the Group IV-containing precursor being di-isopropylcyclopentadienyl tris(dimethylamino) Hafnium;

the Group IV-containing precursor being trimethylgermylcyclopentadienyl tris(dimethylamino) Hafnium;

the oxygen source being water (H₂O);

the oxygen source being oxygen (O₂);

the oxygen source being oxygen plasma;

the oxygen source being ozone (O₃);

the oxygen source being NO;

the oxygen source being N₂O;

the oxygen source being carbon monoxide (CO);

the oxygen source being carbon dioxide (CO₂);

the oxygen source being a combination of water, oxygen, oxygen plasma, ozone, NO, N2O, carbon monoxide, or carbon dioxide;

the temperature of the depositing step ranging from about 50° C. to about 350° C.;

the deposition process being thermal chemical vapor deposition (ThCVD);

the deposition process being thermal atomic layer deposition (ThALD).

the deposition process being plasma enhanced chemical vapor deposition (PECVD);

the deposition process being plasma enhanced cyclic chemical vapor deposition (PECCVD); and

the deposition process being plasma enhanced atomic layer deposition (PEALD).

### NOTATION AND NOMENCLATURE

Certain abbreviations, symbols, and terms are used throughout the following description and claims, and include:

As used herein, the indefinite article “a” or “an” means one or more.

As used herein, the terms “approximately” or “about” mean ±10% of the value stated.

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ(NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used herein, the term “hydrocarbyl group” refers to a functional group containing carbon and hydrogen; the term “alkyl group” refers to saturated functional groups containing exclusively carbon and hydrogen atoms. The hydrocarbyl group may be saturated or unsaturated. Either term refers to linear, branched, or cyclic groups. Examples of linear alkyl groups include without limitation, methyl groups, ethyl groups, n-propyl groups, n-butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “aryl” refers to aromatic ring compounds where one hydrogen atom has been removed from the ring. As used herein, the term “heterocycle” refers to a cyclic compound that has atoms of at least two different elements as members of its ring.

As used herein, the abbreviation “Me” refers to a methyl group; the abbreviation “Et” refers to an ethyl group; the abbreviation “Pr” refers to any propyl group (i.e., n-propyl or isopropyl); the abbreviation “iPr” refers to an isopropyl group; the abbreviation “Bu” refers to any butyl group (n-butyl, iso-butyl, t-butyl, sec-butyl); the abbreviation “tBu” refers to a tert-butyl group; the abbreviation “sBu” refers to a sec-butyl group; the abbreviation “iBu” refers to an iso-butyl group; the abbreviation “Ph” refers to a phenyl group; the abbreviation “Am” refers to any amyl group (iso-amyl, sec-amyl, tert-amyl); the abbreviation “Cy” refers to a cyclic alkyl group (cyclobutyl, cyclopentyl, cyclohexyl, etc.).

The standard abbreviations of the elements from the periodic table of elements are used herein. It should be understood that elements may be referred to by these abbreviations (e.g., Si refers to silicon, N refers to nitrogen, O refers to oxygen, C refers to carbon, etc.).

Any and all ranges recited herein are inclusive of their endpoints x=1 to 4 includes x=1, x=4, and x=any number in between), irrespective of whether the term “inclusively” is used.

Please note that the films or layers deposited, such as zirconium oxide, hafnium oxide, silicon oxide or silicon nitride, may be listed throughout the specification and claims without reference to theft proper stoichiometry (i.e., ZrO₂, HfO₂, SiO₂, SiO₃, Si₃N₄). The layers may include pure (Si, Zr, or Hf) layers, carbide (ZrₒCₚ, HfₒCₚ, SiₒCₚ) layers, nitride (ZrₖNₗ, SiₖNₗ) layers, oxide (ZrₙOₘ, HfₙOₘ, SiₙOₘ) layers, or mixtures thereof, wherein k, m, n, o, and p inclusively range from 1 to 6. For instance, silicon oxide is SiₙOₘ, wherein n ranges from 0.5 to 1.5 and m ranges from 1.5 to 3.5. More preferably, the silicon oxide layer is SiO₂.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. is cross sectional view of an exemplary TFT stack.

### DETAILED DESCRIPTION OF PREFERRED EMBODIMENTS

Thin film transistors (TFTs) are disclosed. The disclosed TFTs include the standard TFT layers shown in the FIG. More particularly, the TFTs 1 include a gate electrode 20 formed on a substrate 10; a Group IV high k oxide gate insulating layer 30 formed over the gate electrode 20 and substrate 10; and a semiconductor channel layer 40 formed over the Group IV high k oxide gate insulating layer 30. Applicants believe that the disclosed TFTs may exhibit low current-leakage (I_{off} lower than 10⁻⁸ A, preferably lower than 10⁻¹⁰A), high electron mobility (μ=higher than 10 cm²/V·s, preferably higher than 12 cm²/V·s), high on/off-currents ratio (Iₒₙ/I_{off} higher than 10⁷, preferably higher than 10⁸), low threshold voltage (Vₜₕ should be lower than 1V, preferably lower than 0.4V) and low threshold voltage shift (ΔVₜₕ should be lower than 0.5V, preferably lower than 0.3V). One of ordinary skill in the art will recognize that the FIG. depicts the bottom gate, top contact TFT embodiment. However, the order of layers in the TFT 1 is not critical, provided that the Group IV high k oxide gate insulating layer 30 remains in direct contact with the gate electrode 20 and the semiconductor channel layer 40.

The substrate 10 is glass or flexible plastic. Examples of flexible plastic substrates include, but are not limited to polyimide, polyether ether ketone (PEEK), polyethylene naphthalate (PEN), polyethylene teraphalate, or combinations thereof. The substrate has a thickness ranging from approximately 5 microns to approximately 200 microns. The flexible plastic substrate may be forced from a straight form into a curved form without damaging the substrate. The flexible substrate must achieve the same electrical properties as non-flexible substrates but with different levels of mechanical stress on the TFT layer caused by the different amounts of bending that the display may experience.

The gate electrode 20 is Al, a CuAl alloy, Cu, a CuMg alloy, a CuP alloy. The gate electrode may be formed on the substrate using standard techniques, including, but not limited to, thermal evaporation of Al, DC sputter of Mo, or electroless deposition of Cu.

The Group IV high k oxide gate insulating layer 30 is ZrO₂ or HfO₂. These high-k materials may produce high ON current (above 10⁻⁴ A) at a low gate voltage (10V or less). These properties may also permit deposition of thinner gate insulting layers (down to 20 nm vs, 100 nm typically practiced in the industry) than prior art silicon oxide or nitride insulating layers because these high k materials reduce the electron tunneling while maintaining high capacitance. Group IV oxide materials also have a passivation effects on the channel layer material, contributing to improved electrical performances. Additionally, Applicants believe that the disclosed insulating layers do not require any intermediary layers between the gate electrode 20 and the insulating layer 30 or between the insulating layer 30 and the semiconductor channel layer 40 as is required for TFTs using high carrier mobility (10 cm²/V·s or more) metal oxide layer, such as zinc oxide, as the insulating layer.

The semiconductor channel layer 40 is selected Indium Gallium Zinc Oxide (IGZO), amorphous IGZO, Indium Tin Zinc Oxide (ITZO), Aluminum Indium Oxide (AlInOx), Zinc Tin Oxide (ZTO), Zinc Oxynitride (ZnON), Magnesium Zinc Oxide, zinc oxide (ZnO), Rare Earth Indium Zinc Oxide (RE)InZnO), InGaZnON, ZnON, ZnSnO, CdSnO, GaSnO, TiSnO, CuAIO, SrCuo, LaCuOS, GaN, InGaN, AlGaN, InGaAlN, or combinations thereof. The semiconductor channel layer is high mobility (>10 cm²/V/s). The semiconductor channel layer is coterminous with the Group IV high k oxide gate insulating layer.

The TFT also includes a source electrode 50 and a drain electrode 60 formed on the Group IV high k oxide gate insulating layer and the semiconductor channel layer.

The TFT may also include an etch stop layer formed on the semiconductor channel layer and the Group IV high k oxide gate insulating layer.

The threshold voltage of the TFT is zero or <10 V. The threshold voltage shift (ΔVₜₕ) is also zero or <2V under negative bias stress. One of ordinary skill in the art will recognize how to determine the threshold voltage, for example, using the Parametric Analyzer from Agilent Technologies to measure the drain current and gate voltage.

Methods of synthesizing the TFTs are also disclosed. The vapor of a Group IV-containing precursor and an oxygen source is introduced into a reaction chamber containing a substrate having a gate electrode thereon. A Group IV high k oxide gate insulating layer is deposited on the gate electrode and the substrate at a temperature of approximately 25° C. to approximately 350° C. using a vapor deposition process.

Suitable vapor deposition processes include chemical vapor deposition (CVD) or atomic layer deposition (ALD). Exemplary CVD methods include thermal CVD, pulsed CVD (PCVD), low pressure CVD (LPCVD), sub-atmospheric CVD (SACVD) or atmospheric pressure CVD (APCVD), hot-wire CVD (HWCVD, also known as cat-CVD, in which a hot wire serves as an energy source for the deposition process), radicals incorporated CVD, plasma enhanced CVD (PECVD) including but not limited to flowable CVD (FCVD), plasma enhanced cyclic CVD (PECCVD), and combinations thereof. Exemplary ALD methods include thermal ALD, plasma enhanced ALD (PEALD), spatial isolation ALD, hot-wire ALD (HWALD), radicals incorporated ALD, and combinations thereof. Super critical fluid deposition may also be used. The deposition process is preferably PECVD, PECCVD, or PEALD.

While Thermal Chemical Vapor Deposition (ThCVD) and Thermal Atomic Layer Deposition (ThALD) are suitable for vapor deposition processes at 250° C. or above, Plasma-enhanced chemical vapor deposition (PECVD) and Plasma-enhanced Atomic Layer Deposition (PEALD) processes may be used for the low temperature vapor deposition processing of the thin-films,

The Group IV precursor may be a tetrakis(alkylamino) Zirconium (Zr(NR₂)₄) or Hafnium (Zr(NR₂)₄) precursor, wherein each R is independently selected from H; a C1-C5 hydrocarbyl group; or a C1-C5 fluoroalkyl group. Exemplary tetrakis(alkylamino) precursors include Zr(NMe₂)₄, Zr(NEt₂)₄, Zr(NMeEt)₄, Hf(NMe₂)₄, Hf(NEt₂)₄, or Hf(NMeEt)₄. These precursors are commercially available or may be synthesized by reacting ZrX₄ or HfX₄, wherein X is a Cl, Br, or I, with Li(NR₂).

The Group IV precursor may be a Cyclopentadienyl-tris(alkylamino) Zirconium (Zr(R³R⁴R⁵R⁶R⁷Cp)(NR¹R²)₃) or Hafnium (Zr(R³R⁴R⁵R⁶R⁷Cp)(NR¹R²)₃) precursor wherein each R¹, R², R³, R⁴, R⁵, R⁶, R⁷, R⁸, R⁹ and R¹⁰ is independently selected from H; a C1-C5 hydrocarbyl group; or a C1-C5 fluoroalkyl group. Exemplary precursors include ZrCp(NMe₂)₃, ZrCp(NEt₂)₃, ZrCp(NMeEt)₃, Zr(MeCp)(NMe₂)₃, Zr(tBu-Cp)(NMe₂)₃, Zr(Et₂Cp)(NMe₂)₃, Zr(Me₃GeCp)(NMe₂)₃, HfCp(NMe₂)₃, HfCp(NEt₂)₃, HfCp(NMeEt)₃, Hf(MeCp)(NMe₂)₃, Hf(tBu-Cp)(NMe₂)₃, Hf(Et₂Cp)(NMe₂)₃, or Hf(Me₃GeCp)(NMe₂)₃. These precursors are commercially available or may be synthesized by reacting ZrX₄ or HfX₄ with (R³R⁴R⁵R⁶R⁷Cp)M, wherein X is Cl, Br, or I and M is Li, Na, or K to form (R³R⁴R⁵R⁶R⁷Cp)ZrX₃ or (R³R⁴R⁵R⁶R⁷C p)HfX₃, which is then reacted with HNR¹R². This latter group is preferred because cyclopentadienyl ligand provides a superior thermal and chemical stability to this family of molecules, hence keeping delivery lines clean for an extended amount of time, and thus dramatically reducing maintenance and replacement of delivery systems.

Applicants believe that the disclosed Group IV precursors will react with and adhere to the underlying substrate and also remain sufficiently flexible on plastic substrates to maintain the TFT function during bending Indeed, the proposed Group IV precursors have sufficient stability, and generate a limited number of particles as opposed to Group IV alkoxides. Particles in the TFT structures may generate cracks, especially for flexible or foldable display devices, that deteriorate the electrical performances of the TFT over time. The resulting TFTs produced using the disclosed Group IV precursors have limited stress, dramatically reducing the risk of de-lamination within the TFT structures.

For deposition of the oxide films on planar surfaces, process parameters may be adjusted to deposit uniform thin-films over large areas in the fabrication of stable and reliable devices. For deposition of the oxide films on devices having vertical steps in the structure, such as vertical thin-film transistors, graded steps, or curved surfaces, sufficient step-coverage is necessary to maintain film integrity, device performance, and yield.

The Group IV precursor is delivered into a reactor in vapor form by conventional means, such as tubing and/or flow meters. The vapor form of the precursor may be produced by a conventional vaporization step such as direct vaporization, distillation, by bubbling. The precursor may be fed in liquid state to a vaporizer where it is vaporized before it is introduced into the reactor. Prior to vaporization, the precursor may optionally be mixed with one or more solvents. The solvents may be selected from the group consisting of toluene, ethyl benzene, xylene, mesitylene, decane, dodecane, octane, hexane, pentane, or others. The resulting concentration may range from approximately 0.05 M to approximately 2 M.

Alternatively, the Group IV precursor may be vaporized by passing a carrier gas into a container containing the precursor or by bubbling of the carrier gas into the precursor. The precursor may optionally be mixed in the container with one or more solvents. The solvents may be selected from the group consisting of toluene, ethyl benzene, xylene, mesitylene, decane, dodecane, octane, hexane, pentane, or others. The resulting concentration may range from approximately 0.05 M to approximately 2 M. The carrier gas may include, but is not limited to Ar, He, or N₂, and mixtures thereof. Bubbling with a carrier gas may also remove any dissolved oxygen present in the precursor. The carrier gas and precursor are then introduced into the reactor as a vapor.

If necessary, the container may be heated to a temperature that permits the Group IV precursor to be in liquid phase and to have a sufficient vapor pressure. The container may be maintained at temperatures in the range of, for example, 0 to 150° C. Those skilled in the art recognize that the temperature of the container may be adjusted in a known manner to control the amount of precursor vaporized. The temperature is typically adjusted to reach a vapor pressure of 0.1-100 torr, preferably around 1-20 torr.

The vapor of the Group IV precursor is generated and then introduced into a reaction chamber containing a substrate. The temperature and the pressure in the reaction chamber and the temperature of the substrate are held at conditions suitable for vapor deposition of at least part of the precursor onto the substrate. In other words, after introduction of the vaporized precursor into the reaction chamber, conditions within the reaction chamber are adjusted such that at least part of the vaporized precursor is deposited onto the substrate to form the insulating layer. One of ordinary skill in the art will recognize that “at least part of the vaporized precursor is deposited” means that some or all of the precursor reacts with or adheres to the substrate. As described in further detail below, a reactant may also be used to help in formation of the insulating layer.

The reaction chamber may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems. All of these exemplary reaction chambers are capable of serving as an ALD or CVD reaction chamber. The reaction chamber may be maintained at a pressure ranging from about 0.5 mTorr to about 20 Torr for all ALD and subatmospheric CVD. Subatmospheric CVD and atmospheric CVD pressures may range up to 760 Torr (atmosphere). In addition, the temperature within the reaction chamber may range from about 0° C. to about 800° C. One of ordinary skill in the art will recognize that the temperature may be optimized through mere experimentation to achieve the desired result.

The temperature of the reactor may be controlled by either controlling the temperature of the substrate holder or controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be kept from approximately 20° C. to approximately 800° C., preferably from approximately 20° C. to approximately 650° C., more preferably from approximately 20° C. to approximately 450° C. for certain flexible plastic substrates, such as polyimide. When a plasma deposition process is utilized, the deposition temperature may range from approximately 0° C. to approximately 350° C. Alternatively, when a thermal process is performed, the deposition temperature may range from approximately 200° C. to approximately 600° C.

Alternatively, the substrate may be heated to a sufficient temperature to obtain the desired insulating film at a sufficient growth rate and with desired physical state and composition. A non-limiting exemplary temperature range to which the substrate may be heated includes from 50° C. to 600° C. Preferably, the temperature of the substrate remains less than or equal to 450° C.

In another alternative, the deposition process may be carried at a substrate temperature being set below a self-decomposition of the precursor. One of ordinary skill in the art would recognize how to determine the self-decomposition temperature of the precursor.

Although lower temperatures are generally desirable for any device fabrication process, they are especially critical in flat panel display manufacture, where large-scale devices are formed on a transparent glass, quartz, or plastic substrates. These transparent substrates may be damaged when exposed to temperatures exceeding 650° C., or even 450° C. for polyimide-based flexible substrates. To address this temperature issue, oxidation processes using a high-density plasma source, such as an inductively coupled plasma (ICP) source, and are able to form oxides with a quality comparable to films produced by 1200° C. thermal oxidation methods.

The reactor contains one or more substrates onto which the films will be deposited. A substrate is generally defined as the material on which a process is conducted. As disclosed above, the substrate is glass or flexible plastic for bottom gate/top contact or bottom gate/bottom embodiments. Alternatively, for top gate/bottom contact and top gate/top contact embodiments, the substrate may be the semiconductor channel layer. One of ordinary skill in the art will recognize that the terms “film” or “layer” used herein refer to a thickness of some material laid on or spread over a surface and that the surface may be a trench or a line.

In addition to the Group IV precursors, a reactant is also introduced into the reactor. The reactant is an oxidizing agent, such as one of O₂; O₃; H₂O; H₂O₂; oxygen containing radicals, such as O⁻ or OH⁻, NO; NO₂; CO; CO₂; carboxylic acids such as formic acid, acetic acid, propionic acid; radical species of NO, NO₂, CO; CO₂; or the carboxylic acids; para-formaldehyde; and mixtures thereof. Preferably, the oxidizing agent is selected from the group consisting of O₂, O₃, H₂O, H₂O₂, oxygen containing radicals thereof such as O⁻ or OH⁻, and mixtures thereof. Preferably, the reactant is plasma treated oxygen, ozone, or combinations thereof.

The reactant may be treated by a plasma, in order to decompose the reactant into its radical form. For instance, the plasma may be generated with a power ranging from about 50 W to about 500 W, preferably from about 100 W to about 400 W. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

For example, the reactant may be introduced into a direct plasma reactor, which generates plasma in the reaction chamber, to produce the plasma-treated reactant in the reaction chamber. Exemplary direct plasma reactors include the Titan™ PECVD System produced by Trion Technologies. The reactant may be introduced and held in the reaction chamber prior to plasma processing. Alternatively, the plasma processing may occur simultaneously with the introduction of the reactant. In-situ plasma is typically a 13.56 MHz RF inductively coupled plasma that is generated between the showerhead and the substrate holder. The substrate or the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the reactant using in-situ plasma is typically less than achieved using a remote plasma source for the same power input and is therefore not as efficient in reactant disassociation as a remote plasma system, which may be beneficial for the deposition of Group IV-containing films on substrates easily damaged by plasma.

Alternatively, the plasma-treated reactant may be produced outside of the reaction chamber. The MKS Instruments' ASTRON® reactive gas generator may be used to treat the reactant prior to passage into the reaction chamber. Operated at 2.45 GHz, 7 kW plasma power, and a pressure ranging from approximately 0.5 Torr to approximately 10 Torr, the reactant O₂ may be decomposed into two O⁻ radicals. Preferably, the remote plasma may be generated with a power ranging from about 1 kW to about 10 kW, more preferably from about 2.5 kW to about 7.5 kW.

The vapor deposition conditions within the chamber allow the disclosed Group IV precursor and the reactant to react and form the insulating film on the substrate.

The disclosed processes fabricate an IGZO-TFT having a low threshold voltage and an excellent stability to stress, while maintaining high mobility, by using a one step fabrication of a high quality and conformal high-k gate insulator.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

We claim:

1. A thin film transistor comprising a gate electrode formed on a substrate; a Group IV high k oxide gate insulating layer formed over the gate electrode and substrate; and a semiconductor channel layer formed over the Group IV high k oxide gate insulating layer, the semiconductor channel layer being selected from the group consisting of Indium Gallium Zinc Oxide (IGZO), amorphous IGZO, Indium Tin Zinc Oxide (ITZO), Aluminum Indium Oxide (AlInOx), Zinc Tin Oxide (ZTO), Zinc Oxynitride (ZnON), Magnesium Zinc Oxide, zinc oxide (ZnO), Rare Earth Indium Zinc Oxide ((RE)InZnO), InGaZnON, ZnON, ZnSnO, CdSnO, GaSnO, TiSnO, CuAlO, SrCuO, LaCuOS, GaN, InGaN, AlGaN, InGaAlN, and combinations thereof.

2. The thin film transistor of claim 1, wherein the Group IV high k oxide gate insulating layer is ZrO₂.

3. The thin film transistor of claim 2, wherein the semiconductor channel layer containing zinc and oxygen.

4. The thin film transistor of claim 3, wherein the semiconductor channel layer is IGZO or (RE)InZnO.

5. The thin film transistor of claim 3, wherein the substrate is glass or plastic.

6. The thin film transistor of claim 1, wherein the Group IV high k oxide gate insulating layer is HfO₂.

7. The thin film transistor of claim 6, wherein the semiconductor channel layer contains zinc and oxygen.

8. The thin film transistor of claim 7, wherein the semiconductor channel layer is IGZO or (RE)InZnO.

9. The thin film transistor of claim 7, wherein the substrate is glass or plastic.

10. A method of synthesizing the thin film transistor of claim 1, the method comprising introducing the vapor of a Group IV-containing precursor and an oxygen source into a reaction chamber containing a substrate having a gate electrode thereon and depositing via a vapor deposition process the Group IV high k oxide gate insulating layer on the gate electrode and the substrate at a temperature of approximately 20° C. to approximately 350° C., the Group IV precursor being selected from the group consisting of:
a. Tetrakis(alkylamino) Zirconium (Zr(NR₂)₄) or Hafnium (Zr(NR₂)₄) wherein each R is independently selected from H; a C1-C5 hydrocarbyl group; or a C1-C5 fluoroalkyl group; and
b. Cyclopentadienyl-tris(alkylamino) Zirconium (Zr(R³R⁴R⁵R⁶R⁷Cp)(NR¹R²)₃) or Hafnium (Zr(R³R⁴R⁵R⁶R⁷Cp)(NR¹R²)₃) wherein each R¹, R², R³, R⁴, R⁵, R⁶, R⁷, R⁸, R⁹ and R¹⁰ is independently selected from H; a C1-C5 hydrocarbyl group; or a C1-C5 fluoroalkyl group.

11. The method of claim 10, wherein the Group IV-containing precursor is selected from the group consisting of tetrakis(dimethylamino) Zirconium, tetrakis(ethylmethylamino) Zirconium, tetrakis(diethylamino) Zirconium, cyclopentadienyl tris(dimethylamino) Zirconium, methylcyclopentadienyl tris(dimethylamino) Zirconium, ethylcyclopentadienyl tris(dimethylamino) Zirconium, t-butylcyclopentadienyl tris(dimethylamino) Zirconium, di-isopropylcyclopentadienyl tris(dimethylamino) Zirconium, and trimethylgermylcyclopentadienyl tris(dimethylamino) Zirconium.

12. The method of claim 11, wherein the Group IV-containing precursor is cyclopentadienyl tris(dimethylamino) Zirconium or methylcyclopentadienyl tris(dimethylamino) Zirconium.

13. The method of claim 10, wherein the Group IV-containing precursor is selected from the group consisting of tetrakis(dimethylamino) Hafnium, tetrakis(ethylmethylamino) Hafnium, tetrakis(diethylamino) Hafnium, cyclopentadienyl tris(dimethylamino) Hafnium, methylcyclopentadienyl tris(dimethylamino) Hafnium, ethylcyclopentadienyl tris(dimethylamino) Hafnium, t-butylcyclopentadienyl tris(dimethylamino) Hafnium, di-isopropylcyclopentadienyl tris(dimethylamino) Hafnium, and trimethylgermylcyclopentadienyl tris(dimethylamino) Hafnium.

14. The method of claim 13, wherein the Group IV-containing precursor is cyclopentadienyl tris(dimethylamino) Hafnium or methylcyclopentadienyl tris(dimethylamino) Hafnium.

15. The method of claim 10, wherein the oxygen source is selected from the group consisting of water H₂O), oxygen (O₂), oxygen plasma, ozone (O₃), NO, N₂O, carbon monoxide (CO), carbon dioxide (CO₂), and combinations thereof.

16. The method of claim 10, wherein the temperature ranges from about 50° C. to about 350° C.

17. The method of claim 10, wherein the vapor deposition process is thermal chemical vapor deposition (ThCVD), thermal atomic layer deposition (ThALD), plasma enhanced chemical vapor deposition (PECVD), plasma enhanced cyclic chemical vapor deposition (PECCVD), or plasma enhanced atomic layer deposition (PEALD).
